(19) United States
(12) Patent Application Publication
(10) Pub. No.: US 2017/0302065 A1
(43) Pub. Date: Oct. 19, 2017

(54) ENERGY MONITORING SYSTEM

(71) Applicant: Sweep Energy, Corona, CA (US)

(72) Inventor: Agustin ROLDAN, Corona, CA (US)

(21) Appl. No.: 15/484,995

(22) Filed: Apr. 11, 2017

Related U.S. Application Data
(60) Provisional application No. 62/322,158, filed on Apr. 13, 2016.
(60) Provisional application No. 62/373,718, filed on Aug. 11, 2016.

(51) Int. Cl. H02H 3/12; G01R 21/133; G01R 22/06; G01R 22/10; G06Q 50/06; H02H 1/00

(52) U.S. Cl. CPC H02H 3/12; G01R 22/10; G06Q 50/06; G01R 21/1331; G01R 22/068; H02H 1/0007

(57) ABSTRACT

This disclosure describes a miniaturized energy-monitoring device that can be powered through an Internet port, which also facilitates the programming the device and transmitting energy consumption data to a remote device for recording and analyzing.

### PRIOR RELATED APPLICATIONS

This application claims priority to U.S. Ser. No. 62/322,158, filed Apr. 13, 2016, and 62/373,718, filed Aug. 11, 2016, each of which is incorporated by reference herein in its entirety for all purposes.

### FIELD OF THE DISCLOSURE

This disclosure generally relates to an apparatus for facilitating the collection of electrical data derived from electrical equipment through a sensor and transmitting that data to a computer over Wi-Fi at varying time intervals in the field of energy management technology.

### BACKGROUND OF THE DISCLOSURE

Energy monitoring devices currently available on the market suffer from several issues. Expensive energy monitors that provide real time energy monitoring technology can cost $1000 or more without any software. This can make it difficult for clients to invest heavily in monitoring all electrical equipment for electrical issues. Only select equipment will use the more expensive energy monitoring technology. There are cheaper energy monitors, but are limited in amount of energy that can be metered, making them difficult for being used in an industry setting where current can reach much higher amperages than what a typical home consumes altogether.

Such monitors also do not provide real time energy monitoring functionality. In many cases, they collect data in intervals of several minutes rather than seconds, making it difficult to get a better understanding of the health of electrical equipment when immediate issues occur.

Further, all of these devices use proprietary means of data transmission through either proprietary radio or wire transmissions. In terms of power access, these devices can only be powered in one way. In many cases, it can either be battery powered or powered by AC/DC power supply, but can not be interchanged or expanded as needed without purchasing more expensive power supplies for every monitor, taking up much needed electrical real estate at electrical plugs, etc. This also can make making energy monitoring of hard to reach equipment impossible.

An energy monitor typically requires a current transformer for measuring electrical properties. Current transformers (CTs) are sensors that measure alternating current, and have a primary winding, a core and a secondary winding, although some transformers, including current transformers, use an air core.

The alternating current in the primary produces an alternating magnetic field in the core, which then induces an alternating current in the secondary. See FIG. 1. The primary circuit is largely unaffected by the insertion of the CT. Accurate current transformers need close coupling between the primary and secondary to ensure that the secondary current is proportional to the primary current over a wide current range. The current in the secondary is the current in the primary (assuming a single turn primary) divided by the number of turns of the secondary. In the illustration on the right, ‘I’ is the current in the primary, ‘B’ is the magnetic field, ‘N’ is the number of turns on the secondary, and ‘A’ is an AC ammeter.

CTs are specified by their current ratio from primary to secondary. The rated secondary current is normally standardized at 1 or 5 amperes. For example, a 4000:5 CT secondary winding will supply an output current of 5 amperes when the primary winding current is 4000 amperes.

An energy monitor typically uses “split core” type CTs for detecting the AC currents, which can be opened and closed over a wire. The split core type is particularly suitable for DIY use, as it can be clipped onto either the live or neutral wire coming into the building, without the need to do any high voltage electrical work. Like any other transformer, a current transformer has a primary winding, a magnetic core, and a secondary winding.

The alternating current flowing in the primary produces a magnetic field in the core, which induces a current in the secondary winding circuit. The current in the secondary winding is proportional to the current flowing in the primary winding:

I_{secondary}=CT_{turnsRatio}×I_{primary}

CT_{turnsRatio}=Turns_{primary}/TURNS_{secondary}

The number of secondary turns in the CT is for example 2000, so the current in the secondary is one 2000th of the current in the primary.

Normally, this ratio is written in terms of current in Amps, e.g. 100:5 (for a 5 Å meter, scaled 0-100 Å). The ratio for the CT above would normally be written as 100:0.05.

Currently the energy monitoring devices do not have Ethernet-ready capability that facilitates connection/programming the device through Ethernet. Also, the energy monitoring devices on the market use either a battery as the power source or power directly from the wall socket, thus are more limited in terms of applicability under different conditions.

### SUMMARY OF THE DISCLOSURE

Energy monitoring devices, systems and methods are described. A single sensor unit has a current transformer as the voltage sensor through induction to measure an analog voltage value, a processor for converting the analog value to a digital value and subsequently transmitting it to a remote device for recording and/or analysis. A housing encloses both the current transformer and the processor and typically has an Ethernet or other connector connecting to the housing for electrical and data coupling to the processor. The Ethernet connector can provide power to the processor by Power over Ethernet, and also facilitates Internet connection when no WiFi or Radio connection is available. Other powering and communication methods are possible. Preferably a number of sensors are deployed to available electric devices, and the sensors collect data for transmission to a remote processor, which analyzes the data, compares it against expected norms or historical data, and initiates any warnings or remedial actions needed.

The invention includes any one or more of the following embodiments, in any one or more combinations thereof:

An energy monitoring system for measuring the electrical energy usage of a plurality of devices powered by a plurality of load conductors connected to a power source, the system comprising:
a housing having a through hole for passing therethrough a load conductor;
a current transformer enclosed within said housing, said current transformer having a center hole for passing therethrough said load conductor and having at least one complete electrical turn in inductive communication with the load conductor such that an output voltage of the current transformer is a function of the level of current in the load conductor, wherein the center hole of said current transformer aligns with said through hole of said housing;
a processor enclosed within said housing, said processor electrically coupled to said current transformer for receiving signals from said current transformer, said processor having an analog-digital converter for converting analog signals to dgital signals;
a power source coupled to the processor for powering said processor;
a wired or wireless communication system on or in said housing for transmitting said digital signal to a remote data processor;
said remote data processor having means for analyzing said digital signal and detecting any deviation from a normal expected signal for a particular device.

An energy monitoring system tor measuring the electrical energy usage ot a plurality of electrically driven devices, the system comprising a plurality of sensor units, each sensor unit comprising:
a housing having a through hole for passing therethrough an electric load conductor for a given electrically driven device;
a current transformer (CT) for measuring a level ot current in the load conductor, said CT enclosed within said housing and having a center hole for passing therethrough said load conductor, wherein the center hole of said CT aligns with said through hole of said housing;
a heat sink inside (he housing for dissipating heat;
a processor coupled to said CT for receiving signas from said CT. said processor having an analog-digital converter for converting analog signals to digital signals, the processor being housed in the housing;
a PoE connector tor powering said processor and for transmitting data to a remote data processor; and
a unique identifier;
the system further comprising a remote data processor for processing said digital signals and detecting any deviation from an expected normal signal; and means for warning a user about a delected deviation.

Any system or sensor unit herein described, further comprising a heat sink within the housing for dissipating heat.

Any system or sensor unit herein described, wherein said processor is powered by a Power over Ethernet (PoE) cable.

Any system or sensor unit herein described, wherein said processor is powered by a PoE cable connecting to an RJ-45 port.

Any system or sensor unit herein described, further comprising an iBeacon protocol for location sensing.

Any system or sensor unit herein described, wherein said processor further comprises a wireless connection module using WiFi (802.11 a. b, g. n, ac, ad, ah, aj, ax, ay), Bluetooth or radiofrequency to connect either directly to said remote data processor or indirectly to said remote data processor through a proxy.

Any system or sensor unit herein described, further comprising a cantilever heat sink within said housing for dissipating heat, said cantilever heat snk comprising a leg having two ends, a first end joining a circuit board inside the housing, a second end at about a right angle to said first end and having a non-planar surface for increasing a surface area thereof.

Any system herein described, wherein said remote data processor further comprises means for an emergency cutoff functionality to shut down a device wherein a malfunction was detected.

Any system herein described, wherein said remote data processor is capable of detecting when the energy monitoring system is malfunctioning or shutoff.

Any system herein described, wherein said remote data processor is capable of detecting when the device powered by a given load conductor is malfunctioning or shut off.

Any system or sensor unit herein described, wherein said power over Ethernet connector in an RJ-45port.

Any system or sensor unit herein described, wherein said processor further comprises a wireless connection module using WiFi (802.11 a, b, g, n, ac, ad, ah, aj, ax, ay). Bluetooth or radiofrequency to optional wireless communication with said remote data processor.

Any system or sensor unit herein described, said heat sink being a cantilever heat sink comprising a leg having two ends, a first end joining a circuit board Inside the housing, a second end at about a right angle to said first end. and said second end being non-planar so as to increasing surface area thereof.

Any system herein described, wherein said remote data processor further comprises means for an emergency cutoff functionality to shut down any electrically driven device wherein a malfunction was detected.

Any system herein described, wherein the water usage WP (acre-foot water) is measured by the following equation:

WP=PP / (Factor A)

wherein PP is pump power (kW/hour), and Factor A is the power needed to lift one acre-foot of water (kW/hour/acre-foot water), and wherein the Factor A is calculated by the following equation:

Factor A=(LP×LD)/E

wherein LP is lift power (kW/hour) needed to lift one acre-fool of water given an efficiency of 100% (1.024 kW/hour), LD is lift depth—the depth of the water pump underground, and E is overall efficiency of the pump as a decimal.

A method of monitonng energy consumption of a load connector, comprising:
providing an energy monitoring system as herein described;
coupling said energy monitoring system with an electrical load powered by load conductors connected to a power source, said coupling done by passing said load conductors through said through hole;
measuring analog electrical values from said current transformer over a predetermined period of time at varying sampling rates;
converting said analog electrical values to digital electrical values; and
transmitting said digital electrical values to said remote data processor; and
analyzing data relating to electrical energy usage of the load and detecting any deviations from an expected norm; and
notifying a user if any deviation is detected.

Any method as herein described, wherein said remote data processor can provide instructions to said senor unit(s).

Any method as herein described, said remote data processor companng said digital electrical values to expected electrical values and detecting any discrepancy as a malfunction, and alerting a user as to said malfunction.

Any method as herein described, wherein if said malfunction is a serious malfunction and said remote data processor directly or indirectly instructs a malfunctioning load conductor to reduce power or shut off. Preferably, if said malfunction is a serious malfunction a visual or auditory warning signal is transmitted to one or more users. Even more preferred, the method including changing at least one setting on a device with a detected deviation.

Any method as herein described, further comprising displaying an energy status of each device on a map.

Any method as herein described, wherein the method is used to monitor water usage by converting energy usage of a water pump to water usage, wherein the water usage WP (acre-foot water) is measured by the following equation:

WP=PP/(Factor A)

wherein PP is pump power (kW/hour), and Factor A is the power needed to lift one acre-foot of water (kW/hour/acre-foot water), and
wherein the Factor A is calculated by the following equation:

Factor A=(LP×LD)/E

wherein LP is lift power (kW/hour) needed to lift one acre-foot of water given an efficiency at 100% (1.024 kW/hour), LD is lift depth—the depth of the water pump underground, and E is overall efficiency of the pump as a decimal.

Any method as herein described, wherein the method is used to monitor water usage of a water pump, compnsing the steps of:
i) measuring and recording flow rate of the water pump with time of occurrence:
ii) measuring and recording water pressure of the water pump with time of occurrence;
iii) calculating and recording an expected flow rate (Fₑ) according to the recorded water pressure;
iv) calculating a predicted flow output (FD) according to the following equation:

Fₒ=Fₑ×T

wherein Fₑ is Predictive Flow rate in Gallons/Minuta. Fₒ is predictive flow output in Gallons, and T is the amount of time in minute that the water pump has been operational; and
v) comparing the predicted flow output to the recorded flow rate to calibrate the predicted flow output.

A method of displaying a plurality of energy monitoring systems on a map interface, comprising:
providing a unique identification serial code for each of said energy monitoring systems;
providing physical location of each of said energy monitoring systems being installed;
verifying said energy monitoring systems;
collecting the physical locations of and energy data being measured by each of said energy monitoring systems; and
displaying said physical locations and said energy data of each of said energy monitoring systems on a map.

A method for using user input to determine malfunctions present in electrical devices being monitored, comprising:
providing a plurality of sensor units, at least one per electrical device being monitored, each said sensor unit having a unique identification code;
accessing a status and a measured energy data from each said sensor unit;
comparing said status and said measured energy data with expected status and expected energy data, and
detecting discrepancies between said status and said measured energy data with expected status and expected energy data, as malfunctions; and
alerting a user as to said malfunctions.

Any method herein described, wherein causes of said malfunctions are either self-detected by each said energy monitoring system or manually entered by an inspecting professional.

The use of the word “a” or “an” when used in conjunction with the term “comprising” in the claims or the specification means one or more than one, unless the context dictates otherwise.

The term “about” means the stated value plus or minus the margin of error of measurement or plus or minus 10% if no method of measurement is indicated.

The use of the term “or” in the claims is used to mean “and/or” unless explicitly indicated to refer to alternatives only or if the alternatives are mutually exclusive.

The terms “comprise”, “have”, “include” and “contain” (and their variants) are open-ended linking verbs and allow the addition of other elements when used in a claim.

The phrase “consisting of” is closed, and excludes all additional elements.

The phrase “consisting essentially of” excludes additional material elements, but allows the inclusions of non-material elements that do not substantially change the nature of the invention.

The following abbreviations are used herein:

| ABBREVIATION | TERM |
|---|---|
| PoE | Power over Ethernet |
| RPM | Revolutions per minute |
| HP | Horse Power |
| GPS | Global Positioning System |
| HTTP | Hypertext Transfer Protocol |
| JSON | JavaScript Object Notation |
| ID | identification |
| LAN | LOCAL AREA NETWORK |

### BRIEF DESCRIPTION OF THE DRAWINGS

FIG. 1. Illustration of basic current transformers.

FIG. 2A-B. Perspective views of the energy monitoring device.

FIG. 3. Perspective view of an alternative design of the energy monitoring device.

FIG. 4. Perspective view of an alternative design of the energy monitoring device.

FIG. 5. A preferred heat sink.

FIG. 6. Flow diagram showing the collection, analysis and storage of measured energy data and accessing these information on a client device.

FIG. 7A. An external view of an integrated energy monitor.

FIG. 7B shows an internal view of the integrated energy monitor.

FIG. 7C. An internal view where the housing has been cut away so the inside is visible. This alternative design allows for quick disconnect of a sensor from the energy monitoring device.

FIG. 8A shows an isometric view of an alternative design of the energy monitoring device.

FIG. 8B. An internal view of the alternative design enclosure of energy monitoring device.

### DETAILED DESCRIPTION

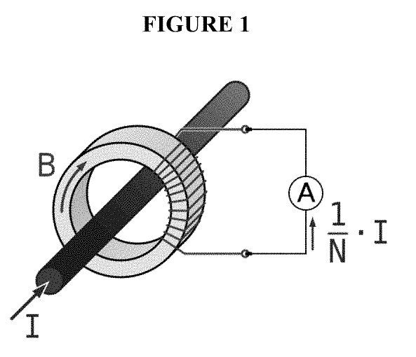

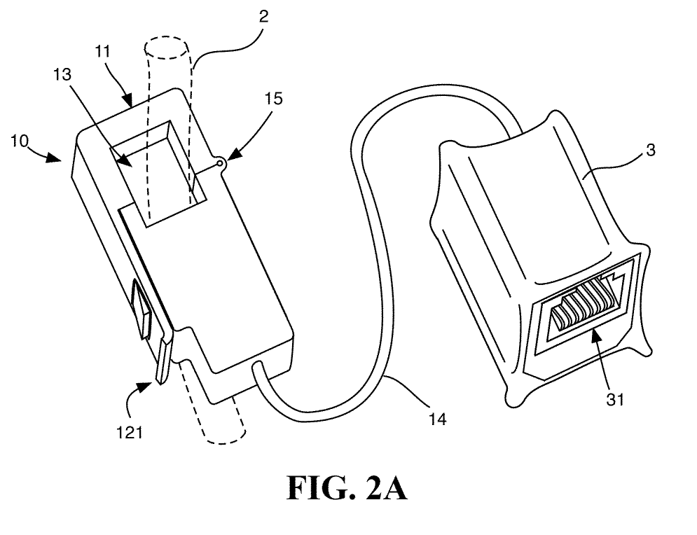

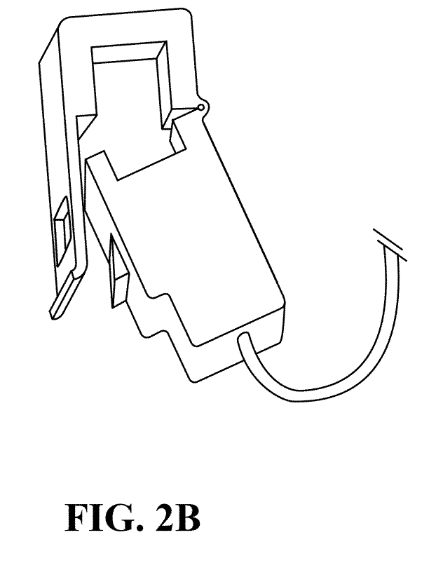

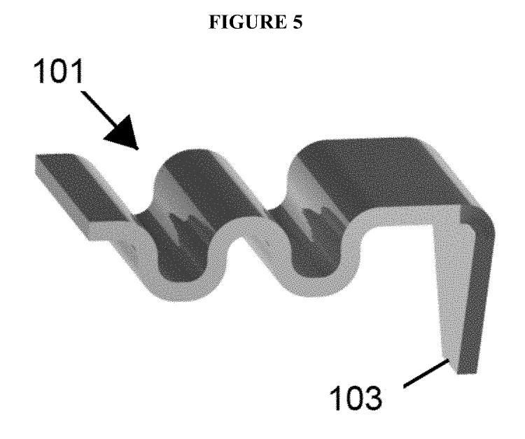

The invention is composed of the following physical features: a current transformer 10 (as shown in FIG. 2) that generates a current value that is proportional to the input current (over a wire that goes through the center hole 13 in the current transformer 10); a rounded plastic housing 3 that has rounded corners that protrude out as shown in FIG. 1; a RJ-45 (Ethernet Port) 31 connector coupled to the current transformer 10 through a cable 14 in order to allow and facilitate programming of the device and provide electrical power to the device through Power Over Ethernet; an internal heat sink 101 (as shown in FIG. 5).

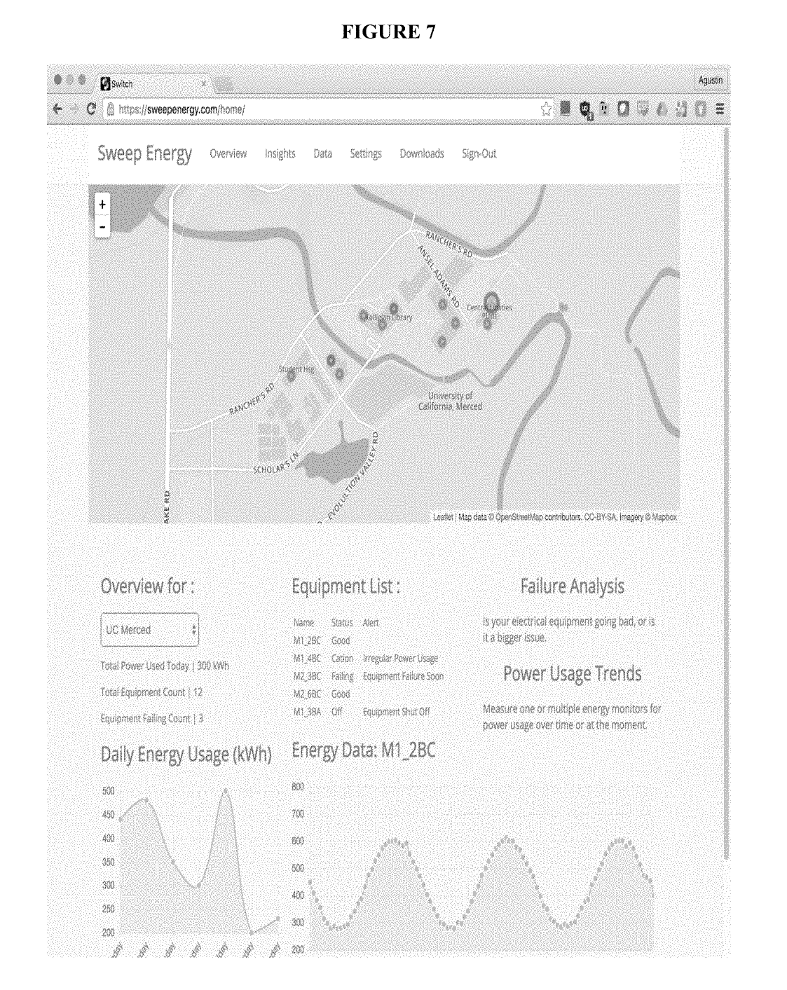

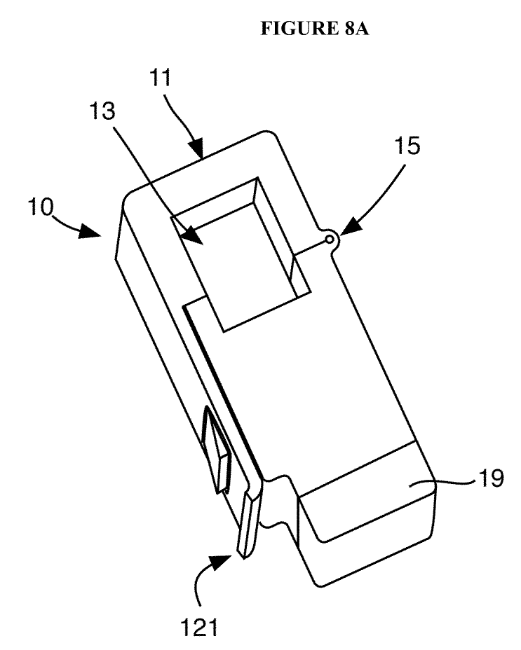

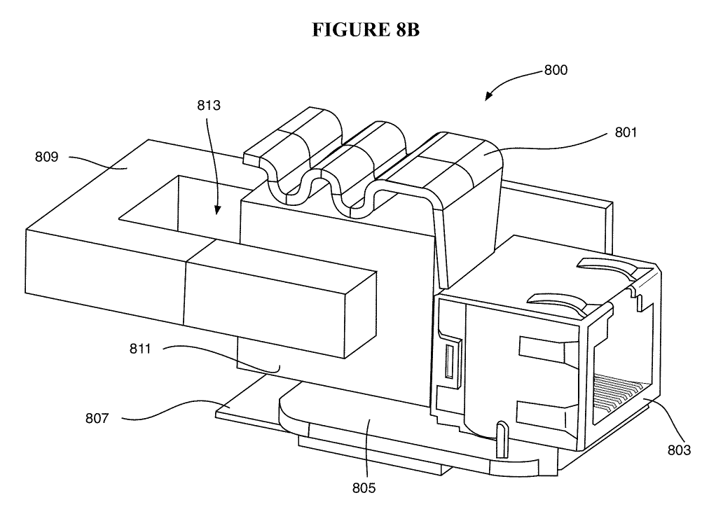

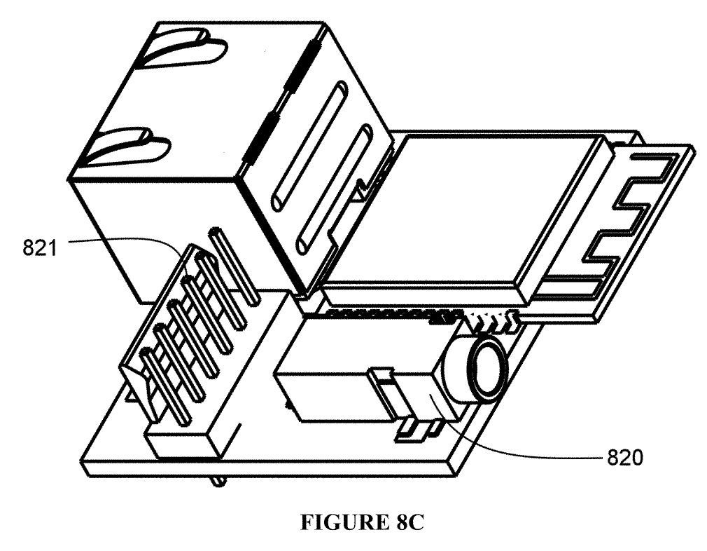

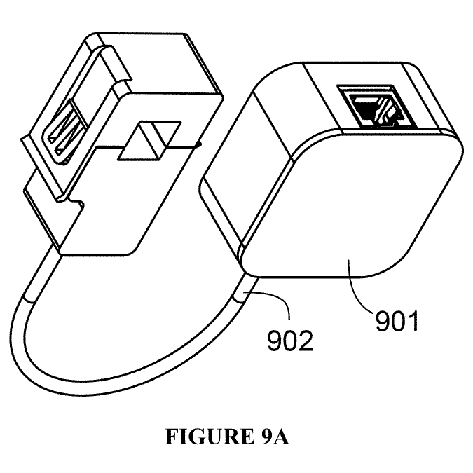

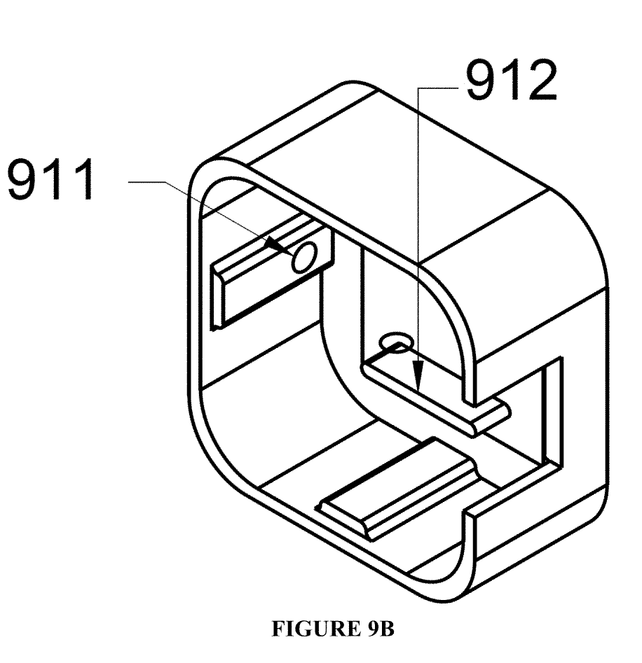

Also needed are a circuit board (not shown) containing all required electrical components to measure and augment sensor values, including a processor (further detailed in FIG. 7A-B) for converting analog signals to digital signals and transmitting the digital signals to a remote device; a computer that collects the transmitted electrical information over LAN/Wi-Fi/radio; a mobile device that can establish first contact with the energy monitor and configure the monitor for extended use; a power supply that may be a AC/DC converter or an external battery unit. The kit requires no physical changes in order to be powered by either, as long as power is supplied through an Ethernet cable of any varying distance from the power source.

The current transformer 10, as shown in FIG. 2A, has a latch 121 so that a user can lift the upper half 11 of the CT to open the through hole 13. The upper half 11 pivots about a hinge 15 to open or close the current transformer, as shown in FIG. 2B. An electrical wire 2 through which the energy consumption is to be monitored can thus be placed into the through hole 13, and the latch 121 is put back in place to hold the wire inside the hole 13. Once installed, the user can begin monitoring electrical values running through the wire. The monitoring device is further connected through a cable 14 to an Ethernet connector 3 that has e.g., an RJ45 port 31. The Ethernet connector allows for both powering the monitoring device as well as transmitting the measured data to a remote server.

In order to power the energy monitor, a user needs to connect the energy monitor to an Ethernet or equivalent cable or an internal power source, such as a battery. The other end of the cable will then be connected to a hub that can supply regulated or unregulated DC power to the device. The Power over Ethernet standard is a preferred means of powering the energy monitor. A battery or AC/DC converter may be used interchangeably to supply power to the device through the Ethernet jack, and depending on the plant layout, both methods could be used.

Power over Ethernet or “PoE” describes any of several standardized or ad-hoc systems that pass electrical power along with data on Ethernet cabling. This allows a single cable to provide both data connection and electrical power to devices such as wireless access points or IP cameras. Unlike standards such as Universal Serial Bus (USB), which also power devices over the data cables, PoE allows long cable lengths. Power may be carried on the same conductors as the data, or it may be carried on dedicated conductors in the same cable.

There are several common techniques for transmitting power over Ethernet cabling. Two of them have been standardized by IEEE 802.3. Since only two of the four pairs are needed for 10BASE-T or 100BASE-TX, power may be transmitted on the unused conductors of a cable. In the IEEE standards, this is referred to as “Alternative B.” Power may also be transmitted on the data conductors by applying a common-mode voltage to each pair. Because twisted-pair Ethernet uses differential signaling, this does not interfere with data transmission. The common mode voltage is easily extracted using the center tap of the standard Ethernet pulse transformer. This is similar to the phantom power technique commonly used for powering audio microphones. In the IEEE standards, this is referred to as “Alternative A.”

A webserver on the energy monitor will be available to connect a mobile device/computer to the energy monitor. This system is in place to allow one to make modifications to settings on the device if it has not yet established a connection to an external Wi-Fi connection. The mobile device's GPS and other software functionality will be used to supplement missing features from the energy monitor in order to define geographic location without the need for an integrated GPS unit and establish that the energy monitor is functioning properly and obtain the necessary configuration information. Alternatively, sensor-to-sensor technology, such as the iBeacon protocol by Apple could be used to establish the location of each sensor unit. Such components are readily available for inclusion in the sensor units.

At start-up, the energy monitor will attempt to connect to a local router to obtain internet access. If it is the very first time starting up, the energy monitor will connect to a local router pre-defined by the user through a mobile application. The mobile app will allow the user to input equipment and environmental values to learn more about the system. For example, such values could include RPM, HP, Voltage, Insulation Rating, GPS coordinates of the equipment's location. The energy monitor will attempt to connect to the internet/local area network and attempt to register itself with a computer. This computer will identify the device by providing a unique ID that will be saved by the energy monitor for annotating future data transmissions. Once a permanent Wi-Fi configuration is supplied by the computer, the energy monitor will restart. From here the energy monitor will function in the following manner.

The current transformer will be attached to the electrical equipment that will be measured for current. One electrified wire from the equipment will need to run through the hole in the center of the current transformer. When an electrical current passes through the current transformer, it will induce a current proportional to the equipment's current usage. The current derived is transformed into an analog voltage value, which will then read by an analog digital converter from a processor in the circuit board.

This microcontroller collects the analog voltage values from the current transformer. In sampling, a set of data samples are collected in succession over the course of 100 ms or more. This list of successive values are then made available through Wi-Fi/radio. Using oversampling, we accomplish gathering different sets of successive voltage values at varying sampling rates. In doing so, we can observe changes in the monitored equipment through external computer software. Oversampling will reduce the energy monitors effective sampling rate, but will extend the overall length of time of collected voltage values.

This data will be sent over Wi-Fi/radio to a software service through the HTTP protocol. The data is preferably structured in the form of the JSON text format to structure and annotate electrical values. This data can be collected by a computer over the internet or local area network. Using the unique identifier given to the energy monitor earlier, the computer will annotate the data as having been received from a specific energy monitor. The transmitted data may be stored by the computer for immediate or later retrieval and analysis. The collected data can be compared with expected data for each device being monitored, and any discrepancies flagged for handling. No electrical data is stored on the energy monitor in preferred embodiments. This reduces size and expense.

If the energy monitor cannot establish a connection with a local area network (LAN) through WiFi/radio, it will attempt to locate another energy monitor within the area, it can then obtain login information and if necessary, send annotated electrical information with the other energy monitor acting as a hub to transmit energy data to the computer on behalf of the other energy monitor.

In the event of internet loss, a local computer/server on the premises can be used to collect energy data indefinitely until a connection can be reestablished. This local computer/server will collect data on behalf of the online service to reduce loss of electrical data. If a connection is lost between online computer and local computer on the premises, a message will be sent through either email or SMS messaging or its equivalent to someone in charge of facility about the internet connectivity issue and recommendations on how the issue may be fixed. This local server/computer's main purpose is to act as a buffer against loss of data before being received over internet. The device in FIG. 7-9 may fulfill this role as the local server/computer that acts as a buffer before going to our service.

In other embodiments, a large plant may be controlled and monitored entirely by local servers, and internet connectivity avoided. This may be an attractive option for security sensitive plants, such as power plants. LANs or WiFi can still be used for wireless communication inside the plant, as desired.

In regards to internal equipment, as shown in FIG. 5, a heat sink 101 that extends in a cantilever fashion is provided. The heat sink 101 has a leg 103 joined by a horizontal portion 105 that has a plurality of non-planar structures 107 to increase the surface area for dissipating heat. Examples of non-planar structures 107 include stamped channels, pins or fins.

The heat sink 101 can be made of any heat conductor, preferably metals, for relatively low cost, such as copper, aluminum, or alloys thereof. Other dielectric materials may also be used for different design needs.

Restrained by the heat generated from the power supply and the current transformer and its small form factor, traditional finned heat sinks would not fit on the device for desired heat dissipation. This cantilever design 101 offers the greatest amount of surface area by the use of stamped channels that increase effective surface area of the metallic material.

By “cantilevered” what is meant is any rigid structural member projecting from a vertical support, especially one in which the projection is great in relation to the depth, so that the upper part is in tension and the lower part in compression. The cantilevered heat sink herein is roughly L shaped (e.g., the two ends are at roughly right angles), wherein at least one of the arms is wavy to provide greater surface area.

As shown in FIG. 5, the bottom tapered portion 103 of the heat sink is mounted to the energy monitors power supply through e.g., the application of solder welding material in order to displace heat away from main electrical components on the energy monitors single circuit board. Heat dissipated through the cantilever design can be done through conduction between the outer plastic case and metallic heat sink. The case design has the least amount of plastic material on the top and bottom portions of the case in order to facilitate the greatest amount of heat dispersal through surface convection from the external environment.

The ribbed protruding corners are used to provide structural rigidity in light of the thinner sides, especially in the case where it is manufactured through 3D printing, but in addition allow the energy monitor to rest more easily along the length of the monitored equipment's shielded wire. However, other shapes are possible.

The number, length and height of channels in the heat sink may be varied to improve heat dissipation properties depending on the available form factor. The heat sink is easier to manufacture by using stamping equipment on flat metal blanks, but molds may be made using traditional metals or 3D printed molds. Our prototype was made using a 3d printed mold that clamps above and below the metal blank and compresses the metal blank into the shape seen in FIG. 5.

By employing the energy monitoring device of this disclosure, the energy monitor costs $10-15 to produce and manufacture compared to what more expensive energy monitors offer at prices starting from $1000+. Thus, such monitors can be extensively used to monitor complex manufacturing operations at an affordable cost. Existing monitors of similar cost do not provide the real time energy monitoring capability that the inventive monitor can, while still utilizing less than 80 mA of current during normal operation. This device is optimized to collect and transmit the greatest amount of data in near real time to an external computer for later processing and filtering. The device has a greater range of current monitoring capability than lower end energy monitors.

Since the device uses Power Over Ethernet, we are able to provide different options to power the device without having to change the device internally. Using Power Over Ethernet, we can for example use one AC/DC power supply or battery pack in order to supply power to 8 or more energy monitors at the same time. Power can be centrally distributed through Ethernet and be made available through varying lengths of Ethernet cable to each device. Remote monitoring can be done in this way to ensure the device receives power but can still function in remote locations.

Also, the device can be easily accessed either over a Wi-Fi hotspot that is generated by the energy monitor itself or through a network. Either method can allow the user to collect electrical data that can be access by a variety of software and hardware technologies. As long as Wi-Fi can be accessed, information may travel freely through the HTTP protocol. Modifications can be made directly to the device by accessing the energy monitors internal webserver to make adjustments onsite or remotely. Devices can be updated for new Wi-Fi passwords, software upgrades and other settings over Wi-Fi.

We required a few iterations of the energy monitoring technology to get to the results shown herein. In our market research we found that companies were struggling to use the energy monitors already in the market for the reasons stated in the background. The first two prototypes exhibited many of the characteristics of other energy monitors and required experimentation in order to solve and find better ways to make it easier to use and integrate in industry, be cost-effective and have a small form factor.

Two additional designs are further described, each having different form factors that utilize the same methods described in the device described above. The main difference between these two devices and the one discussed above is size and the ability to use the electrical data to control the electrical devices connected to the internal plug on the energy monitor through the use of a relay.

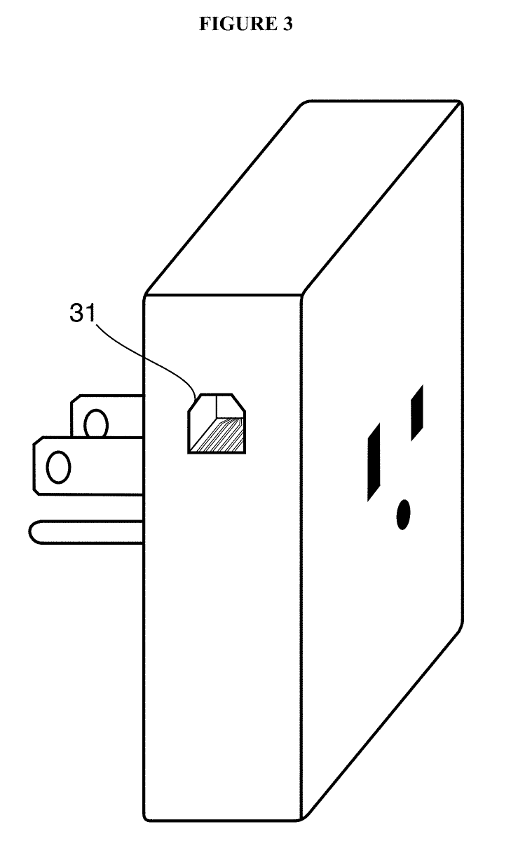

In the design shown in FIG. 3, on the left hand side there is an audio port 31 connection that can be used to accept an analog input from a variety of different sensors. The values of these inputs can affect whether the internal plug turns off or on. For example, in the case of electrical energy monitoring, if the device were to receive electrical signals through a current transformer that imply it is consuming energy beyond a predefined value, it will shut off the device attached to the internal outlet. Another example is if a moisture sensor is attached on the side of the energy monitor, then the energy monitor can engage and disengage a water pump depending on the moisture level of the given area. The device would still have the same abilities to collect electrical voltage values from the set of sensors attached to it at the time. However, because this device is directly inserted into a wall socket, no additional power source is necessary.

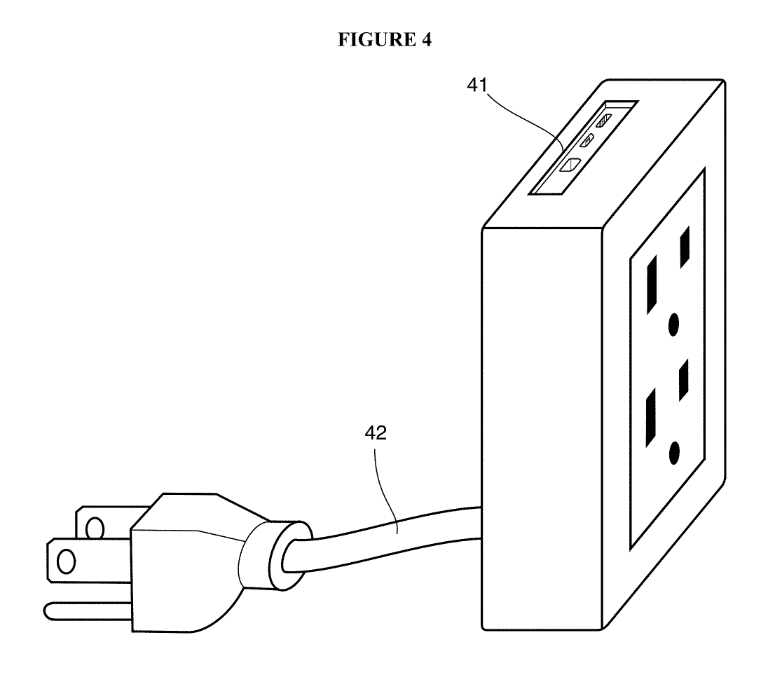

An alternative design, as shown in FIG. 4, has similar functionalities, except that it houses a more powerful internal computer and may act as a hub to collect energy data from other energy monitor devices. The retractable power cord 42 in FIG. 4 allows flexible placement of the device. The energy monitor device also have different ports 41 such as Lightning, microUSB, USB, thunderbolt, USB-C, Firewire (IEEE-1394), etc., for connecting to other energy monitor devices or to a computer for reading the data. A variation of the first generation monitor can be used in places where Wi-Fi is not available to facilitate the collection of energy data which can either be saved inside its own internal storage drive or be sent through more readily available internet through Ethernet.

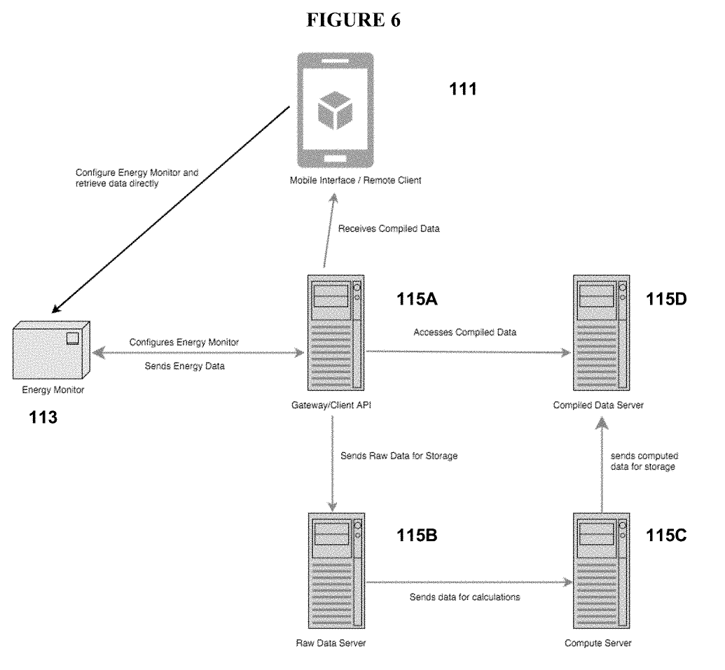

FIG. 6 shows how the measured energy data can be transmitted, analyzed, stored and accessed by using a client device. A gateway server 115A collects and transports the annotated energy data in the form of voltage values and a unique identifier string to identify the device. This data is sent to a computer or set of computers 115B that store data primarily in its hard drives and memory. These computer(s) are then accessed by a set of analytic compute computers/servers 115C. These servers 115C act to run a variety of different tests, which include digital filtering of annotated data to remove device noise, determine power generated, amperage used and calculate the Fast Fourier transform on the energy data to determine the power distribution at different frequencies. This distribution will be saved and compared with future calculations of the Fast Fourier transform. We will be measuring to see if any changes occur in the distribution of power over a range of different frequencies. These calculations are compiled and then sent to a computer(s)/server(s) 115D that can store the compiled results.

These compiled results are readily accessible to an authorized client by using a mobile interface on a mobile device or by using a remote client on a computer 111. The accessed data can then be visualized.

All energy monitors will show up on a map interface. When a marker is selected, it will indicate the statistical findings from the analysis stage inside our service. For example, if the compute stage (processor) determines that the device it is monitoring is off or malfunctioning, then the associated marker will be highlighted red and indicate what the likely problem is. As used herein, a “malfunction” is an unacceptable deviation from expected norms. The tolerance for variance can be user set, and is expected to vary with the device being monitored and or the hazard risk of its operation.

If the processor is unable to identify a cause for any flagged malfunction, the user may input when the issue occurred, what type of issue it was and on what device it occurred, and eventually input a cause or likely cause. In doing so, the user will be able to annotate the data with further information about any new issues that arise. When the system encounters this malfunction again in the form of a similar Fast Fourier distribution, it will use this user reported historical data to help identify the issue.

In the event of dangerous malfunctions, a warning can be sent to a user, a user's mobile device, a centralized alarm system etc. For particularly hazardous issues, an automatic shut off, power down or power reduction can be programmed.

As seen in FIG. 2, the prototype energy monitor is comprised of two components—a component 10 that houses the sensor, and a white component 3 that houses the microprocessor, the two parts linked via wire 14. This prototype was easy to assemble from commercially available parts, and thus sufficed for development and proof of concept work. However, the ultimate goal is to design and build a fully integrated unit with all components in a single housing, and thus a dedicated design will be made, tested and then manufactured in bulk.

FIG. 7 shows an exemplary complete and integrated energy monitor. The benefit of this is the elimination of the wire, reducing any unwanted electrical noise due to the wire, due to the closer connection between the microprocessor and sensor.

In FIG. 7A, the current transformer 10, has the same latch 121 so that a user can lift the upper half 11 of the split core CT to open the through hole 13. The device pivots about hinge 15, and the separation point is indicated by the faint line from the hinge to the opposing side. An electrical wire through which the energy consumption is to be monitored can be placed into the through hole 13, and the latch 121 is put back in place to hold the wire inside the hole 13. Once installed, the user can begin monitoring electrical values running through the wire. The microprocessor component 19 is now integral with the sensor component inside a dedicated housing that includes both components operably connected together.

FIG. 7B shows the detail layout of an integrated energy monitor 800. A split core transformer 809, 811 and an RJ45 Ethernet jack 803 are located on top of a print circuit board 805, which is also coupled to a microcontroller/processor 807 that has Wi-Fi capability. The heat sink 801, as previously described in FIG. 5, is located between the RJ45 Ethernet jack 803 and the secondary winding of the split core transformer 811. The transformer, especially around the windings, is where heat is primarily generated when electric current is induced. As the heat sink 801 has its leg attached to the winding of the split core transformer 811, it can quickly and effectively dissipate the heat away. The split core transformer can be opened in the way illustrated in FIG. 7A to allow an electric wire to be enclosed inside the through hole 813.

FIG. 7C shows the internal circuit board. This circuit board design includes a processor and a removable connector that will allow one to attach and remove a sensor 820 from the circuit board with ease. Pin headers 821 are used to access and program the processor with a removable programmer.

The processor used herein is ESP8266EX by Espressif Systems (ESP32 may also be used), but other processors or chips could be used. Preferably the processor has small footprint, low cost and low power consumption in order for continued operation. The processor also preferably has integrated Wi-Fi, Bluetooth or other wireless connectivity to be able to remotely transmit data and receive instruction for control. The current transformer used herein is SCT013 by YHDC Electronics, but again others could be used. The energy monitoring device preferably has a rechargeable lithium-ion battery by any manufacturer, so that when there is no external power source the monitoring device can still be operational. Power over Ethernet may still be used to remain operational if no battery is present.

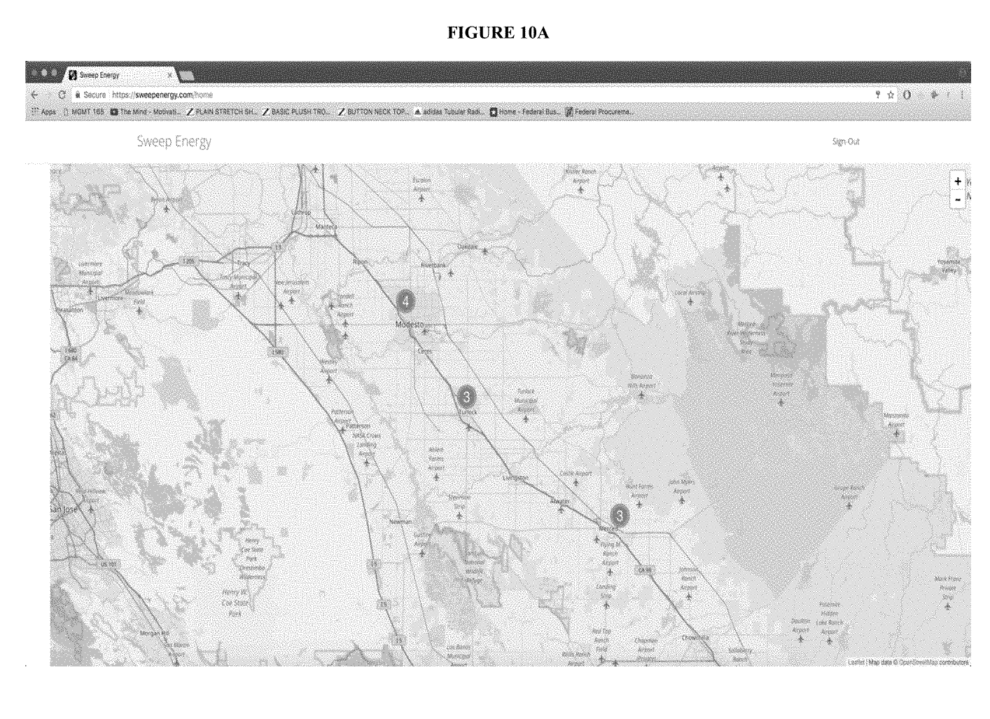

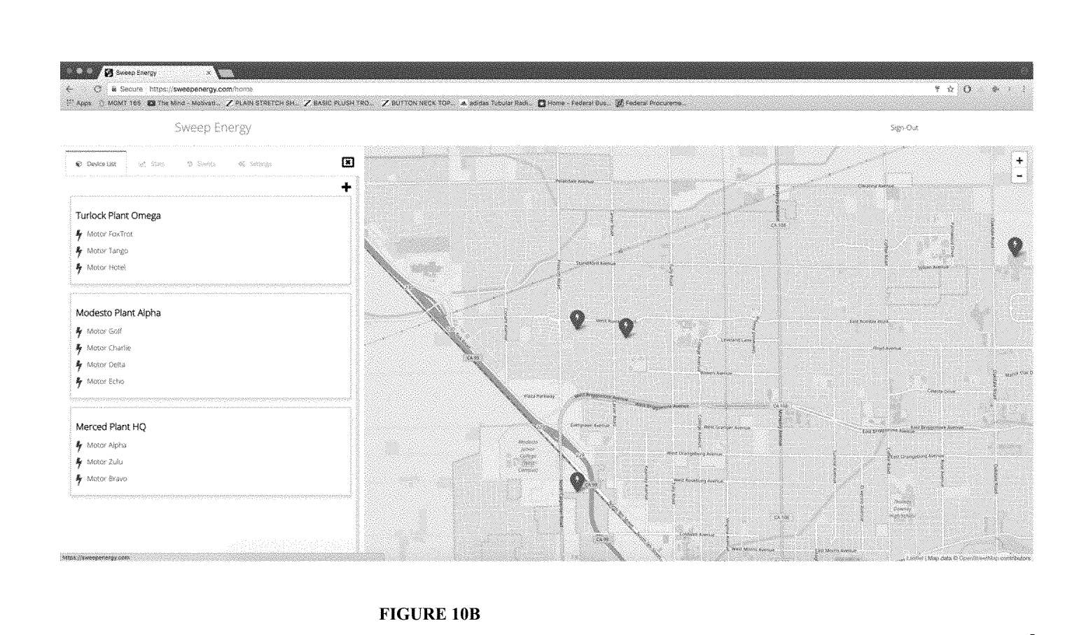

FIG. 8A shows the external case that houses an integrated energy monitor that houses the processor. It is composed of a cap that is press fit or glued onto the main housing base 901. An external wire attaches to the monitor casing either as a through hole connection or through a 3.5 mm audio port 902.

FIG. 8B shows the internal view and is composed of two external ports for an RJ45 connection and audio connector 911. Two fins are attached to secure the electronic circuit board in place 912. Instead of using two fins to secure the circuit board, one may have circular holes that protrudes from the bottom of the case where a screw may be used to secure the circuit board on to the case.

Another application for the devices and systems described herein, is water/gas monitoring through a pump. Given the kW/h usage of a pump/motor as derived by the current, it is also possible to provide an estimate of a production facilities water/gas usage that has flowed through the system. This is made possible by the real time nature of the device. If we know the motors energy usage over time in fine detail, then it is possible to estimate the water/gas flow output passing through a pump.

This method works when the electric meter does not serve uses other than measuring power consumption by the well. Calculating water pumpage using this method requires the energy monitoring system's collected information on the electric pump.

LD—Lift Depth: The depth of the pump underground. This information can then be supplied to the energy monitoring system program through its interface (measured in feet in U.S Customary).

Acre-foot: Defined as the volume of one acre of surface area at a height of one foot (325,851 gallons in U.S customary units).

LP—Lift Power: Kw/hrs needed to lift one acre-foot of water given an efficiency of 100% (1.024 kW in U.S customary units).

PP—Pump Power: kW/hr used by the pump. This number is calculated by the energy monitoring system given the collected data current and voltage input into the pump as collected from the motor plate.

E—Energy: Overall efficiency of the pump as a decimal.

Units—U.S customary units are used for the calculation as its readily used in US measurements, but it may be exchanged for metric units if requested by the user through the system.

Factor A is the kW/h needed to lift one acre-foot of water (units: kW/h/Acre-Foot):

Factor A: (LP×LD)/E

Water Pumped=WP=PP/(Factor A) [Acre-foot in U.S Customary Units]

Therefore:

Water pumped=PP/((LP×LD)/E))=PP×E/LP×LD

Another method to estimate water and gas flow rate is through use of a predictive model that is defined through an artificial neural network. Artificial neural networks (ANNs) are a computational model used in computer science and other research disciplines, which is based on a large collection of simple neural units (artificial neurons), loosely analogous to the observed behavior of a biological brain's axons. Each neural unit is connected with many others, and links can enhance or inhibit the activation state of adjoining neural units. Each individual neural unit computes using summation function. The goal of the neural network is to solve problems in the same way that the human brain would.

Three sets of data are collected to build a predictive water/gas model. First, an energy monitor is connected to one phase of an irrigation or industrial pump to monitor for AC electrical signals and the times they were generated. These analog signals are converted to digital electrical values and then are sent to be processed and broken down to frequency intervals using the fast Fourier transform. This signature is then inserted into a row inside a data base. This database will contain historical frequency intervals and derived features from collected AC electrical signals.

The second set of data that will be collected will be the flow rate. This value may be collected manually by viewing the flow meter reading on an irrigation pump tubing near the filter. This second value is composed of a flow rate and the time of occurrence. This second value is then fed into a separate database that is established based on a set of a features defined in the preceding paragraph. The second value will be collected in 10 minute intervals over two or three hour periods or when drastic changes have been made to the distribution of irrigated water. Once an acceptable amount of data is inserted it may be processed by the deep learning system. The system will require these two specific pieces of data so that it may find a correlation between the amount of current consumed by irrigation pump and the expected flow rate for the given current consumed.

The third value collected is the water pressure that the irrigation pump is running at to provide more information about the current operational state of the pump. The water pressure may be collected manually or, preferably, through a sensor. This value will be collected in 10 minute intervals over two or three hour periods or when drastic changes have been made to the distribution of irrigated water.

The training data that is collected will be composed of a variety of different irrigation pumps and will be used to normalize and identify the expected flow rate. When the system discovers a new current consumption usage pattern it will ask the user, “what is the current flow rate and water pressure?” The computer system will remember the corresponding correlation between current output, flow rate and water pressure. Once a sufficient amount of data is inserted into the artificial neural network, any new subsequent pieces of data will be analyzed and will return a prediction of the expected flow rate Fₑ. Then the predictive total flow output Fₒ can be estimated by the following equation:

Fₒ=Fₑ×T

wherein
Fₑ is Predictive Flow rate in Gallons/Minute, obtained from the predictive model or may be provided as training data;
Fₒ is Predictive Flow output in Gallons, meaning the volume of water received; and
T is the amount of time in minute that the electric motor has been operational.

In the event that it predicts incorrectly, the user may update the predictive value with the actual value and the system will recognize the inaccuracy and attempt to correct itself when it sees that specific current usage pattern again for the given user. The AC signal data will be the primary source to derive predicted flow rates with pressure being another possible predictive value that can be used to identify correct functionality and accuracy.

The predicted flow output will then be used to predict a total flow output when only a water flow rate is available or measured briefly due to some reason. This is especially useful when there is no other means of measuring water usage at the water pump, and the estimation obtained from the energy monitoring system would be a good approximation for further analysis.

Each of the following is incorporated by reference herein in its entirety for all purposes:

U.S. Pat. No. 4,965,513 Motor current signature analysis method for diagnosing motor operated devices

U.S. Pat. No. 8,447,541 Energy usage monitoring with remote display and automatic detection of appliance including graphical user interface

US20080255782 Devices, Systems, and Methods for Monitoring Energy Systems

US20120303554 Energy Monitoring System and Method

U.S. Pat. No. 8,996,188 System and method for home energy monitor and control

What is claimed is:

1. An energy monitoring system for measuring the electrical energy usage of a plurality of devices powered by a plurality of load conductors connected to a power source, the system comprising:
a) a housing having a through hole for passing therethrough a load conductor;
b) a split core current transformer enclosed within said housing, said current transformer having a center hole for passing therethrough said load conductor and having at least one complete electrical turn in inductive communication with the load conductor such that an output voltage of the current transformer is a function of the level of current in the load conductor, wherein the center hole of said current transformer aligns with said through hole of said housing;
c) a processor enclosed within said housing, said processor electrically coupled to said current transformer for receiving signals from said current transformer, said processor having an analog-digital converter for converting analog signals to digital signals;
d) a power source coupled to the processor for powering said processor;
e) a wired or wireless communication system on or in said housing for transmitting said digital signal to a remote data processor;
f) said remote data processor having means for analyzing said digital signal and detecting any deviation from a normal expected signal for a particular device.

2. The system of claim 1, further comprising a heat sink within the housing for dissipating heat.

3. The system of claim 1, wherein said processor is powered by a cable using a Power over Ethernet (PoE) protocol.

4. The system of claim 1, wherein said processor is powered by a PoE cable connecting to an RJ-45 port.

5. The system of claim 1, wherein said processor further comprises a wireless connection module using WiFi (802.11 a, b, g, n, ac, ad, ah, aj, ax, ay), Bluetooth or radiofrequency to connect either directly to said remote data processor or indirectly to said remote data processor through a proxy.

6. The system of claim 1, further comprising a cantilever heat sink within said housing for dissipating heat, said cantilever heat sink comprising a leg having two ends, a first end joining a circuit board inside the housing, a second end at about a right angle to said first end and having a non-planar surface for increasing a surface area thereof.

7. The system of claim 1, wherein said remote data processor further comprises means for an emergency cutoff functionality to shut down a device wherein a malfunction was detected.

8. The system of claim 1, wherein said remote data processor is capable of detecting when the energy monitoring system is malfunctioning or shut off.

9. The system of claim 1, wherein said remote data processor is capable of detecting when the device powered by a given load conductor is malfunctioning or shut off.

10. The system of claim 1, wherein at least one of said devices is a water pump and said system is used to monitor water usage by converting energy usage of said water pump to water usage.

11. The system of claim 10, wherein the water usage WP (acre-foot water) is measured by the following equation:
WP=PP/(Factor A)
wherein PP is pump power (kW/hour), and Factor A is the power needed to lift one acre-foot of water (kW/hour/acre-foot water), and
wherein the Factor A is calculated by the following equation:
Factor A=(LP×LD)/E
wherein LP is lift power (kW/hour) needed to lift one acre-foot of water given an efficiency of 100% (1.024 kW/hour), LD is lift depth—the depth of the water pump underground, and E is overall efficiency of the pump as a decimal.

12. An energy monitoring system for measuring the electrical energy usage of a plurality of electrically driven devices, the system comprising a plurality of sensor units, each sensor unit comprising:
a) a housing having a through hole for passing therethrough an electric load conductor for a given electrically driven device;
b) a split core current transformer (CT) for measuring a level of current in the load conductor, said CT enclosed within said housing and having a center hole for passing therethrough said load conductor, wherein the center hole of said CT aligns with said through hole of said housing;
c) a heat sink inside the housing for dissipating heat;
d) a processor coupled to said CT for receiving signals from said CT, said processor having an analog-digital converter for converting analog signals to digital signals, the processor being housed in the housing;
e) a PoE connector for powering said processor and for transmitting data to a remote data processor; and
f) a unique identifier;
the system further comprising:
g) a remote data processor for processing said digital signals and detecting any deviation from an expected normal signal; and
h) means for warning a user about a detected deviation.

13. The system of claim 12, said power over Ethernet connector comprising an RJ-45 port.

14. The system of claim 12, wherein said processor further comprises a wireless connection module using Wi-Fi (802.11 a, b, g, n, ac, ad, ah, aj, ax, ay), Bluetooth or radiofrequency to optional wireless communication with said remote data processor.

15. The system of claim 12, said heat sink being a cantilever heat sink comprising a leg having two ends, a first end joining a circuit board inside the housing, a second end at about a right angle to said first end, and said second end being non-planar so as to increasing surface area thereof.

16. The system of claim 12, wherein said remote data processor further comprises means for an emergency cutoff functionality to shut down any electrically driven device wherein a malfunction was detected.

17. A method of monitoring energy consumption of a load connector, comprising:
a) providing an energy monitoring system of claim 1;
b) coupling said energy monitoring system with an electrical load powered by load conductors connected to a power source, said coupling done by passing said load conductors through said through hole;
c) measuring analog electrical values from said current transformer over a predetermined period of time at varying sampling rates;
d) converting said analog electrical values to digital electrical values;
e) transmitting said digital electrical values to said remote data processor;
f) analyzing data relating to electrical energy usage of the load and detecting any deviations from an expected norm; and
g) notifying a user if any deviation is detected.

18. The method of claim 17, said remote data processor comparing said digital electrical values to expected electrical values and detecting any discrepancy as a malfunction, and alerting a user as to said malfunction.

19. The method of claim 17, wherein said remote data processor provides instructions to said sensor unit(s).

20. The method of claim 17, further comprising: changing at least one setting on a device with a detected deviation.

21. The method of claim 17, further comprising displaying an energy status of each said device on a map.

22. The method of claim 17, wherein if said deviation is a serious malfunction said remote data processor directly or indirectly instructs a malfunctioning load conductor to reduce power or shut off.

23. The method of claim 17, wherein the method is repeated over time to generate a historical log of energy usage.

24. The method of claim 17, wherein the method is used to monitor water usage by converting energy usage of a water pump to water usage, wherein the water usage WP (acre-foot water) is measured by the following equation:
WP=PP/(Factor A)
wherein PP is pump power (kW/hour), and Factor A is the power needed to lift one acre-foot of water (kW/hour/acre-foot water), and
wherein the Factor A is calculated by the following equation:
Factor A=(LP×LD)/E
wherein LP is lift power (kW/hour) needed to lift one acre-foot of water given an efficiency of 100% (1.024 kW/hour), LD is lift depth—the depth of the water pump underground, and E is overall efficiency of the pump as a decimal.

25. The method of claim 17, wherein the method is used to monitor water usage of a water pump, comprising the steps of:
i) measuring and recording flow rate of the water pump with time of occurrence;
ii) measuring and recording water pressure of the water pump with time of occurrence;
iii) calculating and recording an expected flow rate (Fₑ) according to the recorded water pressure;
iv) calculating a predicted flow output (Fₒ) according to the following equation:
Fₒ=Fₑ×T
wherein Fₑ is Predictive Flow rate in Gallons/Minute, Fₒ is predictive flow output in Gallons, and T is the amount of time in minute that the water pump has been operational; and
v) comparing the predicted flow output to the recorded flow rate to calibrate the predicted flow output.

26. A method of displaying a plurality of energy monitoring systems of claim 1 on a map interface, comprising:
a) providing a unique identification serial code for each of said energy monitoring systems;
b) providing physical location of each of said energy monitoring systems being installed;
c) verifying said energy monitoring systems;
d) collecting the physical locations of and energy data being measured by each of said energy monitoring systems; and
e) displaying said physical locations and said energy data of each of said energy monitoring systems on a map.

27. A method for using user input to determine malfunctions present in electrical devices being monitored, comprising:
a) providing a plurality of sensor units of claim 1, at least one per electrical device being monitored, each of said sensor units having a unique identification code;
b) accessing a status and a measured energy data from each of said sensor units;
c) comparing said status and said measured energy data with expected status and expected energy data;
d) detecting discrepancies between said status and said measured energy data with expected status and expected energy data; and
e) alerting a user to said discrepancies.

28. The method of claim 27, wherein causes of said discrepancies are either self-detected by each said energy monitoring system or manually entered by an inspecting professional.
